(19) United States
(12) Patent Application Publication
(10) Pub. No.: US 2003/0150101 A1
(43) Pub. Date: Aug. 14, 2003

(54) Printed circuit board with buried resistor and manufacturing method thereof

(75) Inventors: Keon-Yang Park, Seoul (KR); Jang-Kyu Kang, Daejeon (KR); Seok-Kyu Lee, Chongju (KR)

Correspondence Address: MORGAN LEWIS & BOCKIUS LLP, 1111 PENNSYLVANIA AVENUE NW, WASHINGTON, DC, 20004, US

(73) Assignee: Samsung Electro-Mechanics Co., Ltd.

(21) Appl. No.: 10/097,406

(22) Filed: Mar. 15, 2002

(30) Foreign Application Priority Data
Dec. 4, 2001 (KR) 2001-76218

(51) Int. Cl. H01C 7/00; H05K 1/16

(52) U.S. Cl. 29/621; 338/34; 29/830; 29/832; 174/260

(57) ABSTRACT

Disclosed are a PCB with buried or embedded resistors and a method for manufacturing the same. The PCB comprises: a resinous, electrically insulating substrate; a circuit pattern formed on the substrate; at least a pair of spaced resistor terminations, formed in a certain pattern on the substrate, each comprising a metal pad covered with a conductive protective layer; a thin-film resistor formed between the resistor terminations with electrical connection thereto; and an over-coating layer formed of one-part ink, covering the resistor and the resistor terminations. To be provided with a desired resistance, optionally, the resistor may be grooved by laser trimming. The PCB can have a desired resistor resistance which is uniform without being affected by environmental factors.

### BACKGROUND OF THE INVENTION

1. Field of the Invention

The present invention relates to a printed circuit board (PCB) with buried resistors or embedded resistors and a manufacturing method thereof. More particularly, the present invention relates to a PCB in which is embedded a resistor whose resistance is uniform without being affected by the external environment, and a method for manufacturing the same.

2. Description of the Prior Art

Provided for mounting parts of electric circuits thereon, a PCB has wires formed by printing methods. Such parts are arranged and connected to each other according to certain circuit designs. Most of the parts constituting electronic circuits exist in chip form, and discrete chip resistors are directly mounted on the surface of a PCB in order to achieve signal connections (e.g., signal transmission among ICs, external signal input/output, etc.) between the parts. However, employment of discrete chip resistors may not meet the requirement for high-density integration according to high-speed signal processing, and in addition, causes reliability problems.

To overcome the disadvantages, new materials, substances and processes, which can be used in place of the discrete chip resistors, were developed.

Buried or embedded resistors are a result of this development. Resistors, which are a kind of passive elements, are embedded or buried inside or outside a PCB irrespective of the size of the PCB itself. That is, passive elements are, at least in part, integrated into a PCB. Therefore, a PCB with buried or embedded resistors is characterized by no discrete chip resistors mounted or connected onto the surface thereof because passive elements are partially included in the board. The space, which discrete passive elements occupy, may be provided for other parts, allowing a high-density integration on the board. Thus, the employment of embedded resistors reduces the size of the board, which supports the trend of slimness and smallness in electronic appliances. Furthermore, making solder joints unnecessary and being not affected by thermal or mechanical impacts or shocks, buried or embedded resistors are suitable for use in devices for which high reliability is required.

In order to fabricate buried resistors, there have been developed a variety of processes, some of which are commercially used as follows.

A first example is a ceramic thick film typed resistor. Its fabrication usually starts with the coating of ceramic resistor paste on a substrate. Thereafter, the coated paste is sintered at as high as 850 to 900° C., and covered with a protective glass layer, followed by re-sintering. Detailed fabrication of such a thick film type resistor is taught in U.S. Pat. No. 5,510,594. According to this patent, an electrode of a conductive material containing silver is formed on an electric insulating substrate such as alumina by printing. Then, a thick-film resistor of an electric resistive material containing cermet is electrically connected to the electrode on the substrate. Subsequently, the thick-film resistor is subjected to laser trimming to obtain a desired resistance. Then, a film of an electric insulating material is formed on the insulating substrate to protect the electrode and resistor. This resistor is applied to ceramic substrates, but is unsuitable for direct use in resinous substrates such as epoxy-glass, polyimide, etc.

Next, a thin film typed resistor is exemplified as a buried resistor. An electrical resistance metal layer or film is formed inside of a PCB, substituting for a resistor to be mounted on the surface of the PCB. In this regard, a process for fabricating a PCB with buried resistors by use of a thin resistance material, such as that manufactured by Ohmega Technologies, Inc., identified as “Ohmega-Ply®”, has already been used commercially. For instance, U.S. Pat. No. 4,892,776 discloses a PCB with a buried resistor, which is fabricated using a circuit board material comprising a support layer; at least one electrical resistance layer of a nickel-phosphorous composition, adhered to the support layer; and a conductive layer adhered to the resistance layer. For the fabrication of the PCB, a photolithographic process is employed. Applied to the inside of the substrate, the buried resistor is protected by insulating material and thus does not need additional processes for protection from the external environment.

Another example is a polymer thick film typed resistor which is established by coating polymeric resistor paste on a substrate and thermally drying (curing) it. The polymer thick-film typed resistors may be discriminated from each other according to their positions on the substrate: an internal type which is obtained by coating paste on an internal layer; and an external type which is obtained by coating paste on the outermost layer.

As for the internal type, its prior arts can be found in EP 0 569 801 A1 and Japanese Pat. Laid-Open No. Hei 6-61651. According to these patents, resistors are formed as thick film on an inner side of PCB provided with conductor tracks on two sides by printing and surface mounted devices (SMDs) are arranged on the outer side of the PCB. The PCBs are pressed in such a way that the inner sides face each other, with an intermediate layer made of dialectic material interposed therebetween. The internal type does not require an additional resistor-protecting layer against external environments since the resistors are formed in the multi-layered PCB. However, the internal type suffers from poor resistance predictability and poor tolerance limitation control.

Usually, the external type is fabricated by screen-printing electrical resistance polymer on a substrate, and then printing solder mask (or solder resistor) to protect the polymeric resistor.

The conventional external type technique for manufacturing a PCB with embedded resistor is described in conjunction with the figures.

FIGS. 1a to 1e illustrate the fabrication of PCB with embedded resistors, in a stepwise manner.

First, a conductive layer (i.e., copper thin film) is formed on a substrate 1 and a photoresist film or dry film layer 3 and 3′ is deposited over the outermost layer, followed by light exposure, development and copper etching to form a predetermined pattern of conductive tracks 2 and 2′, as shown in FIG. 1a.

Next, FIG. 1b contains schematic cross sectional and plan views after-the dry film 3 and 3′, which is used as an etching resist, is stripped to expose the copper terminations 2 and 2′, which are spaced from each other.

Subsequently, a carbon-based resistor paste 5 is screen-printed between the (copper) terminations 2 and 2 with the aid of a squeeze blade 4, as shown in FIG. 1c. The resistor paste is typically made of an insulating material such as carbon black in combination with a thermosetting organic vehicle or a polymeric matrix.

After the printing of the resistor paste, it is thermally cured at about 150-250° C. to create a thick-film resistor which is electrically connected to the copper terminations 2 and 2′, as shown in FIG. 1d.

Finally, a blanket of solder mask ink (photo solder resist ink; PSR ink) 7 is deposited over the resulting structure of FIG. 1d to protect the thick-film resistor 6 against the external environment, that is, to prevent the thick-film resistor 6 from being damaged physically and chemically and to prevent its resistance properties from being changed due to moisture or temperature, as shown in FIG. 1e. The solder mask layer 7 is typically prepared from a composition comprising an ethereal solvent or an acetate solvent, a binder or matrix component consisting essentially of acid anhydride-modified epoxy acrylate (UV-setting resin) and a cresol novolak epoxy resin or isocyanurate epoxy resin (thermosetting resin), an inorganic filler selected from among barium sulfate, talc, silica and mixtures thereof, an acryl monomer with bi- or higher functionality, a crosslinking agent based on dicyandiamide or melamine, and optionally, a leveling agent, a defoaming agent, a dispersing agent, a UV-setting catalyst, pigment and the like.

However, the above-illustrated external type resistor is disadvantageous in that the term between the steps of FIGS. 1b and 1c is long enough to allow for the oxidization of the copper terminations which are exposed to the exterior. What makes the matter worse, when coated with the liquid resistor paste and dried, the oxidized terminations undergo further oxidation. In this case, so deteriorated is the adhesiveness between the resistor and the terminations that the resistance increases. In consideration of the resistance increase attributable to moisture, control of the resistor resistance to a value lower than a desired one has been suggested. However, this method is unsuitable for mass production.

As for ceramic PCBs, almost none of their dimensions exceed 10×10 cm. However, plastic PCBs usually have a dimension of as large as 50×60 cm. When resistor paste is applied onto the plastic PCBs, the paste thickness is apt to differ from position to position even within the same panel. The non-uniformity of the paste thickness causes non-uniformity in resistance across the panel, deteriorating the reliability of the product.

The resistance of the resistor can be calculated according to the following equation 1:

$$R = SR \times \frac{L}{W \times T} \qquad [ 1 ]$$

wherein R stands for resistance of a resistor; SR for specific resistance of a sheet; L for length of the resistor; W for width of the resistor; and T for thickness of the resistor.

As seen in the Equation 1, the resistance decreases with the increase of the resistor thickness. In practical printing processes, it is difficult to print paste of a uniform thickness over a panel owing to the tolerance of the printing machine itself, and thus it is hard to achieve desired resistance uniformly across a panel by a printing method. In this regard, the achievement of a desired resistance may resort to laser trimming, as disclosed in U.S. Pat. No. 5,510,594. Whereas it can be easily conducted and guarantee a desired value on a ceramic board as in the patent, the laser trimming is difficult to apply to the larger plastic board not only because it is conducted inaccurately over a larger area, but also because the resistance is altered by laser heat.

In addition, the solder mask (or solder resist) ink used in conventional PCBs allows the resulting coating to have an excellent appearance because of the employment of a binder with a high molecular weight. This method, though, is inconvenient because it is a two-part system which causes trouble for curing. Particularly, the solvent of the conventional solder mask adversely affects the lower coating (resistor paste). The resistor is changed in resistance as it absorbs moisture upon the drying of the solder mask. Thus, the resistance which is ultimately obtained may greatly deviate from a target value.

Therefore, there remains a need for the development of a novel PCB with embedded resistors in which a desired resistance can be achieved with minimal variation with external environments.

### SUMMARY OF THE INVENTION

It is an object of the present invention to provide a PCB with embedded resistors, which shows minimal resistance variation with external environments.

It is another object of the present invention to provide a PCB with embedded resistors, in which a desired resistance may be achieved.

It is a further object of the present invention to provide a method for manufacturing such a PCB with embedded resistors.

In accordance with the first aspect of the present invention, there is provided a printed circuit board with an embedded resistor, comprising:

a resinous, electrically insulating substrate;

a circuit pattern formed on the substrate;

at least a pair of spaced resistor terminations, formed in a certain pattern on the substrate, each comprising a metal pad covered with a conductive protective layer;

a thin-film resistor formed between the resistor terminations with electrical connection thereto; and

an over-coating layer formed of one-part ink, covering the resistor and the resistor terminations.

In the second aspect of the present invention, there is provided a method for manufacturing a printed circuit board with an embedded resistor, comprising the steps of:

a) building at least one pair of spaced resistor metal pads, along with a circuit pattern, on a resinous insulating substrate;

b) depositing a blanket of a solder mask layer over the resulting substrate structure of the step a);

c) selectively removing the solder mask layer to form a solder mask opening through which the resistor metal pads and the region therebetween is exposed;

d) forming a conductive protective layer onto each of the resistor metal pads to give resistor terminations;

e) forming a thick-film resistor between the resistor terminations with an electrical connection of the resistor to the terminations; and

f) covering the resistor and resistor terminations with an over-coating layer of one-part ink.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1e are diagrams stepwise illustrating conventional processes for manufacturing a PCB with embedded resistors;

FIGS. 2a to 2g are schematic cross-sectional views stepwise illustrating processes for manufacturing a PCB with embedded resistors according to one embodiment of the present invention.

FIG. 3a is a schematic cross-sectional view showing an resistor structure trimmed by laser;

FIGS. 3b to 3d are plan views showing a double cut, an L-cut and a single cut formed in resistors, respectively;

FIGS. 4a and 4b are plan views showing the formation of a first groove and a second groove by double cut laser trimming, respectively.

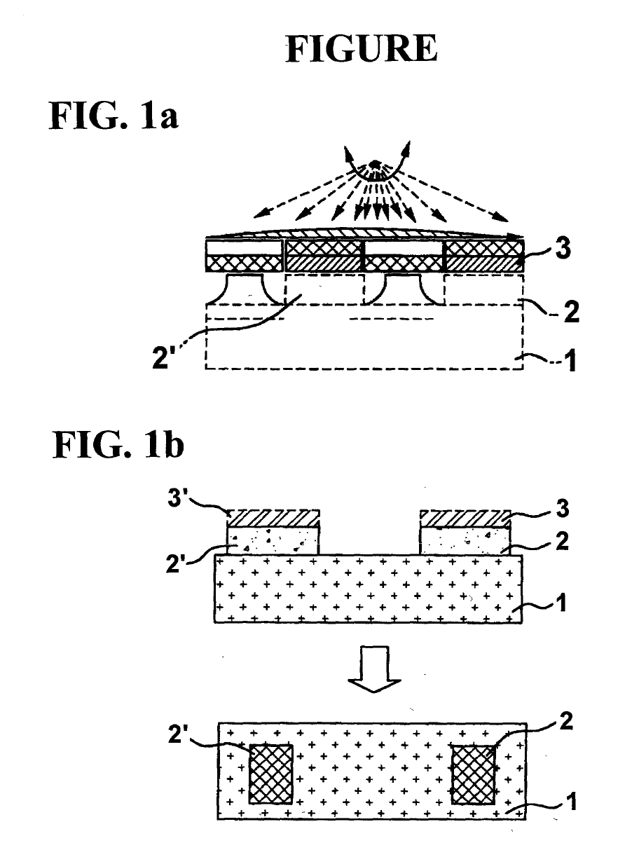

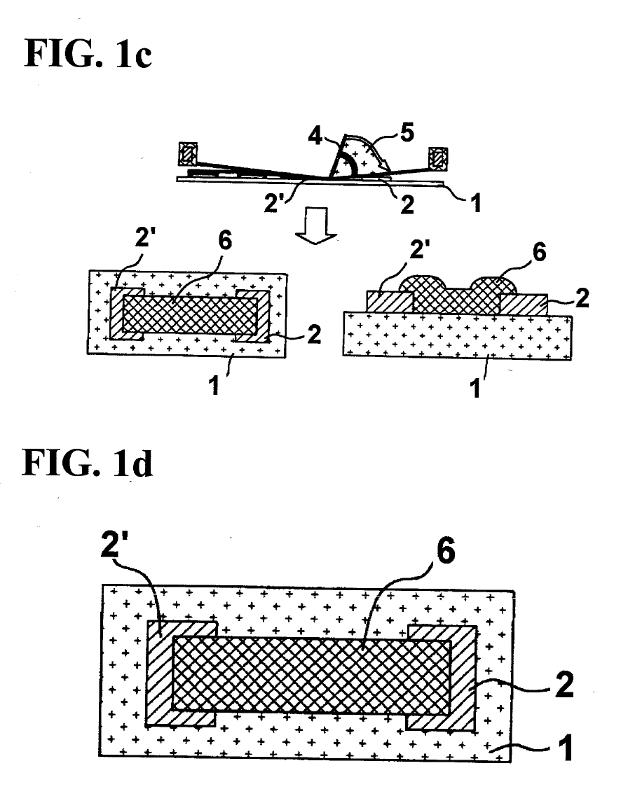

### DETAILED DESCRIPTION OF THE PREFERRED EMBODIMENTS

The application of the preferred embodiments of the present invention is best understood with reference to the accompanying drawings, wherein like reference numerals are used for like and corresponding parts, respectively.

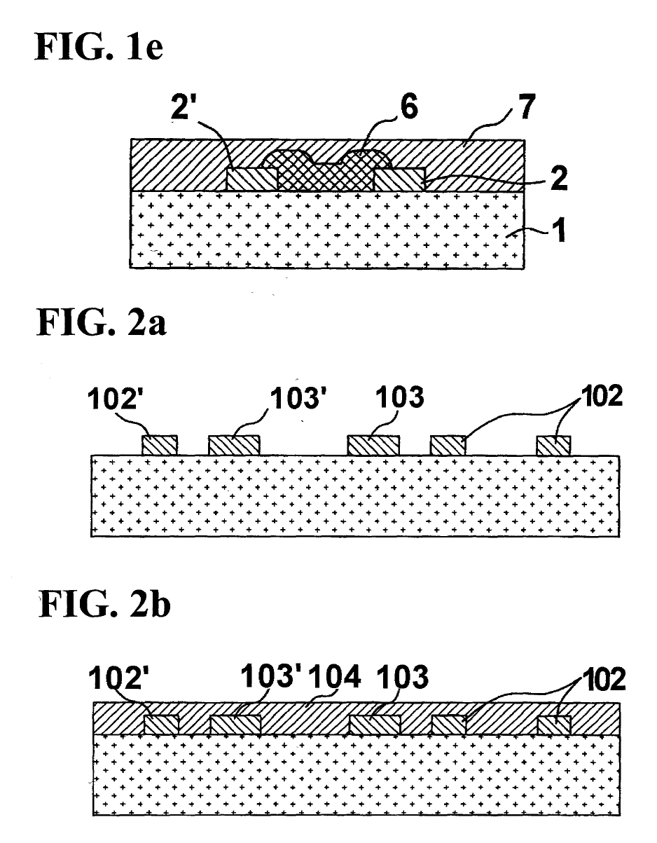

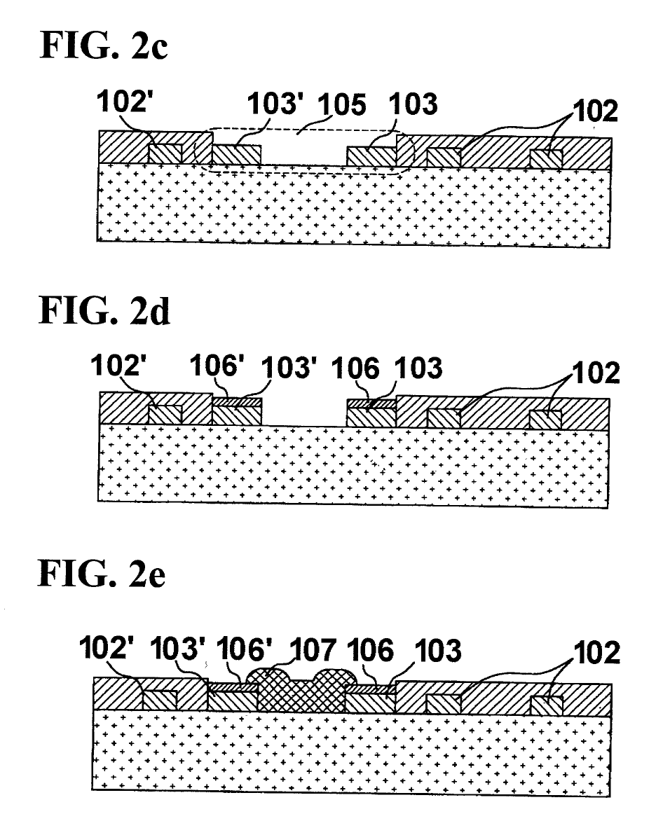

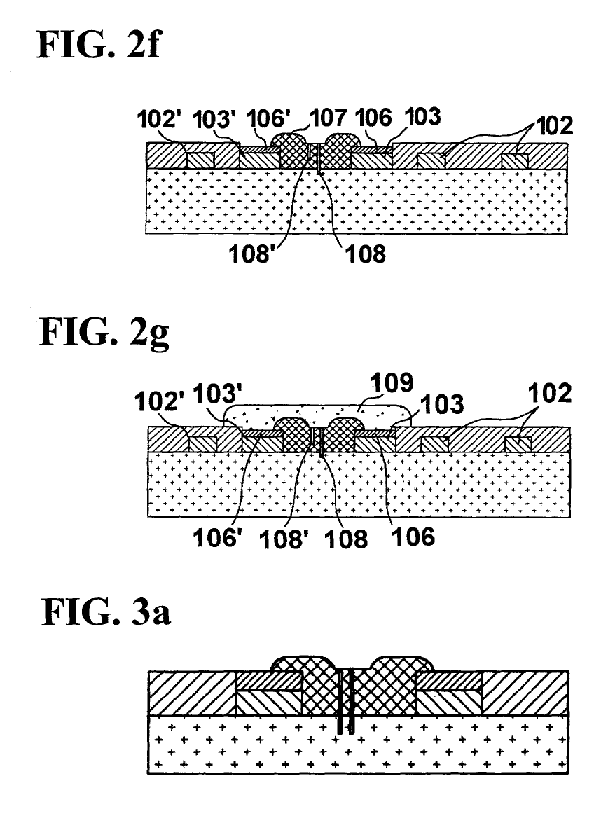

FIGS. 2a to 2g stepwise illustrate the manufacture of a PCB with embedded resistors in accordance with the present invention.

Referring to FIG. 2a, a pattern of a conductive metal layer such as a bare copper layer is formed on a substrate 1. Possessing an electrically insulating property, the substrate 1 for use in the present invention may be made of epoxy-coated glass, polyimide, cyanate ester, bismaleimide-triazine (BT), polytetrafluoroetylene, and the like. However, it must be noted that the materials as mentioned above do not limit the scope of the present invention, but are only illustrative, and any one used as a PCB substrate in the art may be used without specific limitations. The patterned metal layer may be formed by common methods well known in the art, photolithography is preferred. By way of example, electroless plating and electrolytic plating are conducted to form a metal layer on a substrate, and a dry film or photoresist is applied onto the metal layer, after which the resulting structure is exposed to light, developed to selectively etch the metal layer, and removed of the dry film which acts as an etching resist to give a patterned metal layer. Thus, at least a pair of spaced resistor metal pads 103 and 103′ along with a circuit patterns 102, 102′ are built on the substrate.

The resistor metal pads are preferably copper pads with a thickness of about 18 to 45 μm.

FIG. 2b is a schematic cross sectional view after a blanket of a solder mask layer 104 is deposited over the resulting structure of FIG. 2a to protect the patterned metal layer. The solder mask also acts as a resist against the plating to be subsequently conducted for the formation of a conductive protective layer. The thickness of the solder mask layer 104 is thick enough to cover the copper layers 102, 102′, 103 and 103′ and is preferably on the order of 30 to 40 μm. Useful as the solder mask is PSR ink (two-part system ink).

FIG. 2c is a schematic cross sectional view after a solder mask opening 105 is formed in such a way that the resistor metal pads 103 and 103′ and an area therebetween are exposed. In this regard, a dry film is overlaid on the solder mask layer 104 and subjected to exposure and development to selectively etch a region of the solder mask layer 104 which stretches from one metal pad to the other.

Subsequently, a pair of the exposed resistor metal pads 103 and 103′ are covered with conductive protective layers 106 and 106′, respectively, to give resistor terminations, as shown in FIG. 2d. Preferably, the conductive protective layers 106 and 106′ are formed by plating nickel and gold in due order. Electroless plating is preferable. For example, the nickel coating ranges in thickness from about 3 to 5 μm while the gold coating is on the order of 0.05 to 0.08 μm. The resistor terminations determine the electrical length of the resistor to be formed later. In the present invention, the formation of the conductive protective layers (preferably Ni/Au coating) can prevent the metal pads from being oxidized by ambient moisture and other environmental factors between the metal patterning step and the resistor coating step to be described later. Because it is difficult to directly plate gold on the resistor copper pads, nickel is first applied onto the resistor copper pads before the deposition of gold, so as to produce Cu/Ni/Au resistor terminations.

Afterwards, a thick film resistor 107 is preferably formed between the resistor terminations in such a way that the resistor 107 partially covers each of the resistor terminations for electrical connection, as shown in FIG. 2e. The formation of the thick film resistor 107 can be achieved, for example, by screen printing resistor paste, preferably carbon-based resistor paste and then thermally curing it. The carbon-based resistor paste comprises a resinous binder in which filler particles are dispersed at such a controlled amount as to obtain a desired sheet resistivity. Exemplary compositions of resistor paste useful in the present invention are given in Table 1, below.

TABLE 1

| | Carbon Resistor Paste | | |
|---|---|---|---|
| | Type-I | Type-II | Type-III |
| Resin | Solid BPA¹⁾/Epoxy | Phenol/Vinyl | Epoxy/Acryl |
| Filler | Ag/Graphite/C | Au/Talc/C | Pd/Graphite/C |
| Filler Content | 20-30/10-20/2.5-5 | 1-3/20-30/4-8 | 1-2/10-25/5-10 |
| (wt %) | | | |
| Solvent | Ethanol | Buthanol | Ethanol |
| Viscosity | 700 ps | 500 ps | 800 ps |
| Storage Period | 6 Months | 3 Months | 3 Months |

Screen-printing of the resistor paste may resort to methods well known in the art. By way of example, a template with an aperture is first positioned as a screen mask near the surface of the substrate on which the resistor is to be formed, and the mask is loaded with the resistor paste. Then, a squeeze blade is drawn across the surface of the screen mask to press the resistor paste through the aperture and onto the surface of the substrate. Thereafter, the screen-printed resistor paste is thermally cured at the curing temperature to be determined according to the employable resistor paste, preferably about 150 to 250° C. Thus, there may be produced a thick-film resistor having required thickness, preferably about 15 to 40 μm.

As mentioned above, it is difficult for screen-printed resistors to have the desired resistance uniformly across the conventional resinous PCBs which thus have the problem of causing high rejection rates in practical application. In accordance with the preferable embodiment of the present invention, laser trimming is selectively utilized to obtain desired resistance uniformly, as will be described later.

FIG. 2f is a schematic cross sectional view after grooves 108 and 108′ are defined in the thick-film resistor 107 by laser trimming to control the resistance of the resistor to a desired value. Useful in the formation of the grooves 108 and 108′ is UV laser or IR laser with a laser spot size of preferably about 30 to 50 μm.

Standard laser trim cuts are exemplified by a single cut, a double cut, and an L-cut. As a rule, when forming grooves in resistors by laser trimming, the resistors are increased in resistance. Therefore, in the case that a laser trimming process is conducted, the resistor should be controlled to have a resistance less than a desired value prior to the trimming process.

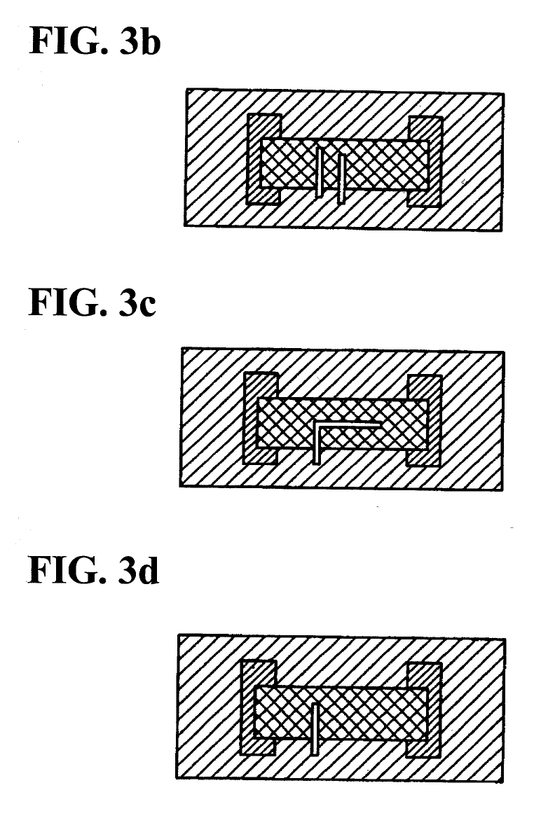

FIG. 3a is a schematic cross sectional view showing a resistor structure trimmed by laser, while FIGS. 3b to 3d are plan views showing a double cut, an L-cut and a single cut formed in resistors, respectively.

In accordance with the present invention, any laser trimming manner may be adopted if it can guarantee a desired resistance in the resistor. Generally, when using carbon-based paste resistors, L-cut laser trimming as shown in FIG. 3c results in a resistance exceeding a desired value while a single cut, as shown in FIG. 3d, may deteriorate the trimming resolution. Because most ceramic resistors are composed of inorganic materials, they are affected very little by the heat generated during the laser trimming. On the other hand, the heat of the laser has a large influence on the organic components of carbon paste. For these reasons, the resistance of the resistor trimmed in a single cut or an L-cut by laser is apt to be over the target value. It is preferable that the laser trimming is carried out in a double cut manner.

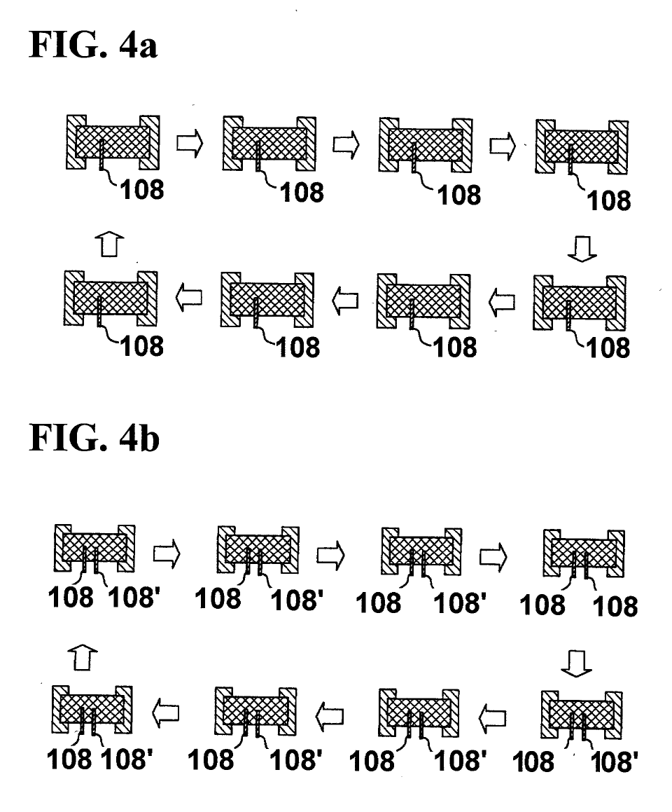

FIGS. 4a and 4b contain plan views showing the exemplified formation of a first groove 108 and a second groove 108′ by double cut laser trimming, respectively.

Where 8 resistors, each having a target resistance of 10 Ω, are positioned on a panel, a first resistor is single cut by laser trimming to form a first groove 108 to provide a resistance of about 9.5 Ω to the first resistor, and a second to an eighth resistors are treated in the same manner to create a resistance of 9.5 Ω for each resistor, as shown in FIG. 4a. Preferably, the first groove 108 penetrates partially through the resistor in a widthwise direction. Additionally, the laser trimming is preferably conducted in such a way that the first groove 108 is extended to the substrate underneath the resistor to improve the fixation effect of the resistance.

Next, as shown in FIG. 4b, all of the resistors with the first grooves 108 are trimmed by laser in a single cut manner to form a second groove 108′ in each resistor, thereby controlling the resistance to the target value of 10 Ω. At a certain time interval, the resistors are twice allowed to undergo single cut laser trimming. Hence, the double cut done by conducting the single cut twice at a certain time interval has the advantage of minimizing the heat-caused variation of the resistance.

Turning now to FIG. 2g, the resistor (or laser-trimmed resistor) and the exposed resistor terminations are protected from the external environment by an over-coating layer 109 which is made of a one-part system ink which is of low hygroscopic capacity and superior in thermal resistance and impact resistance.

In accordance with the present invention, the one-part system ink (preferably, one-part, thermosetting ink) is employed for use in the over-coating layer. Representative of such ink includes about 30 to 40% by weight of an epoxy-based thermosetting resin, about 3 to 5% by weight of a thermosetting crosslinking agent, and about 50 to 60% by weight of an inorganic filler such as silica, as main components thereof, in combination with a curing catalyst, pigment, and other additives (leveling agent, defoaming agent, dispersing agent, etc). Since the over-coating ink guarantees excellent coating properties only by heating, the curing process is finished within a short time period. In addition, the over-coating ink enjoys the advantage of having little affect on the lower coats because of its lower solvent content compared to two-part system inks. Particularly where the laser trimming is conducted, the use of one-part system ink is required because the two-part system ink may cause moisture absorption and accelerate changes in the resistance.

Summarized in Table 2 are compositions of one-part system ink useful in the present invention.

TABLE 2

| Component | Composition | Note |
|---|---|---|
| Main Binder | BPA liquid Epoxy 30 wt % | Thermosetting |
| Curing | Epoxy Reactive diluent 9 wt % | Thermosetting |
| Agent | Dicyandiamide 3 wt % | |
| Catalyst | Modified Polyamine 1 wt % | Curing Catalysis |
| Filler | Mix. of 2 Silica Species 55 wt % | Control of Strength and |
| | | Moisture absorption |
| Pigment | Phthalocyanin Green 0.5 wt % | Color Control |
| Additive | Leveling, Defoaming & | Coating condition and |
| | Dispersing Agent 1.5 wt % | workability improvement |

The BPA liquid epoxy used as a main binder is represented by the following chemical formula 1:

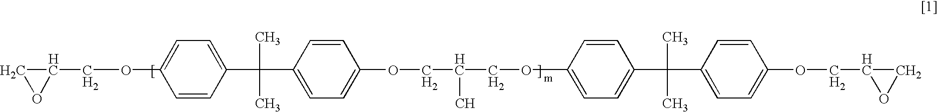

wherein m is 1 or less.

Serving to protect the laser-trimmed resistor and resistor terminations from the external environment, the over-coating layer 109 is formed by screen-printing the one-part ink to such a thickness (preferably about 15 to 25 μm) as to cover the laser-trimmed resistor and the partially exposed resistor terminations and thermally curing the ink, for example at a temperature of about 150 to 170° C.

The present invention enjoys advantages in terms of the following three aspects:

First, metal used as resistor terminations, especially copper, is readily oxidized in the course of the fabrication of PCBs to deteriorate the bondability at the boundary between the resistor terminations and the resistor, which leads to an increase in resistance. However, the formation of the conductive protective layer (preferably, Ni/Au) on the metal terminations prevents the oxidation of the metal, resulting in keeping the resistance relatively constant, as demonstrated in the following test.

On resistor terminations made of Cu and Cu/Ni/Au, a temperature cycle test, a temperature humidity test, and an IR reflow test were conducted. The test results are given in Tables 3 to 5, below.

In the temperature cycle test, heating was performed with 100 cycles in the order of at −65° C. for 30 min for a first stage, at 25° C. for 15 min for a second stage, at 125° C. for 30 min for a third stage, and at 25° C. for 15 min for a fourth stage.

For the temperature humidity test, an incubator was used in which the samples were maintained at 85° C. at a relative humidity of 85% for 168 hours.

The IR reflow test was carried out with two thermal cycles of a first stage at 150° C. for 50 sec, a second stage at 190° C. for 50 sec, a third stage at 245° C. for 50 sec, and a fourth stage at 90° C. for 50 sec.

TABLE 3
Temperature Cycle Test

| | Cu Termination | | Cu/Ni/Au Termination | |
|---|---|---|---|---|
| | Before T.C | After T.C | Before T.C | After T.C |
| Avg. Resistance | 10.15 | 11.69 | 9.86 | 9.75 |
| (Ω) | | | | |

| | | |
|---|---|---|
| Avg. Resistance | +15.18 | −1.32 |
| Change (%) | | |

TABLE 4
Temperature Humidity Test

| | Cu Termination | | Cu/Ni/Au Termination | |
|---|---|---|---|---|
| | Before T.H | After T.H | Before T.H | After T.H |
| Avg. Resistance | 10.34 | 16.18 | 10.02 | 10.31 |
| (Ω) | | | | |

| | | |
|---|---|---|
| Avg. Resistance | +56.43 | +2.29 |
| Change (%) | | |

TABLE 5
IR Reflow Test

| | Cu Termination | | | Cu/Ni/Au Termination | | |
|---|---|---|---|---|---|---|
| | | IR | IR | | IR | IR |
| | Before IR | Round 1 | Round 2 | Before IR | Round 2 | Round 3 |
| Avg. Resistance (Ω) | 10.17 | 10.41 | 10.65 | 10.20 | 10.17 | 10.15 |
| Avg. Resist. Change (%) | Standard | +2.36 | +4.72 | Standard | −0.29 | −0.49 |

Second, the over-coating layer made of one-part system ink protects the resistors and the resistor terminations against environmental factors such as moisture, and physical and chemical impacts and shocks. Thus, this prevents the change of the resistance due to environmental factors, thereby improving the reliability of the product.

A temperature cycle test, a temperature humidity test, and an IR reflow test were conducted on resistors obtained with the conventional two-part system ink and one-part system ink useful in the present invention. The results are given in Tables 6 to 8, below.

TABLE 6
Temperature Cycle Test

| | | | One-part | |
|---|---|---|---|---|
| | Solder Mask Ink | | Thermosetting Ink | |
| | Before T.C | After T.C | Before T.C | After T.C |
| Avg. Resistance (Ω) | 4.7 | 4.9 | 4.9 | 4.9 |

| | | |
|---|---|---|
| Avg. Resist. Change | +4.3 | 0.0 |
| (%) | | |

TABLE 7
Temperature Humidity Test

| | | | One-part | |
|---|---|---|---|---|
| | Solder Mask Ink | | Thermosetting Ink | |
| | Before T.H | After T.H | Before T.H | After T.H |
| Avg. Resistance (Ω) | 4.6 | 4.9 | 4.6 | 4.8 |

| | | |
|---|---|---|
| Avg. Resist. Change | +6.5 | +4.3 |
| (%) | | |

TABLE 8
IR Reflow Test

| | Solder Mask Ink | | | One-part Thermoset. Ink | | |
|---|---|---|---|---|---|---|
| | Before | IR | IR | Before | IR | IR |
| | IR | Round 1 | Round 2 | IR | Round 1 | Round 2 |
| Avg. Resistance (Ω) | 5.0 | 5.0 | 5.0 | 5.0 | 5.0 | 5.0 |
| Avg. Resist. Change (%) | Standard | 0.0 | 0.0 | Standard | 0.0 | 0.0 |

Finally, a desired resistance can be guaranteed for the resistor by optionally establishing grooves therein through laser trimming. When the resistor screen-printed on a plastic PCB shows non-uniform resistance, laser trimming may be conducted to adjust the resistance to a desired value.

As described hereinbefore, the PCB with embedded resistors of the present invention can have a desired resistor resistance which is uniform without being affected by environmental factors.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

What is claimed is:

1. A printed circuit board with an embedded resistor, comprising:
a resinous, electrically insulating substrate;
a circuit pattern formed on the substrate;
at least a pair of spaced resistor terminations, formed in a certain pattern on the substrate, each comprising a metal pad covered with a conductive protective layer;
a thin-film resistor formed between the resistor terminations with electrical connection thereto; and
an over-coating layer formed of one-part ink, covering the resistor and the resistor terminations.

2. The printed circuit board as set forth in claim 1, wherein the resistor has a groove trimmed by a laser.

3. The printed circuit board as set forth in claim 2, wherein the groove comprises a first and a second groove.

4. The printed circuit board as set forth in claim 3, wherein the first groove penetrates partially through the resistor in a widthwise direction.

5. The printed circuit board as set forth in claim 4, wherein the first groove is extended to the substrate underneath the resistor.

6. The printed circuit board as set forth in claim 1, wherein the metal pad is made of copper.

7. The printed circuit board as set forth in claim 6, wherein the conductive protective layer has a bi-layer structure composed of nickel and gold.

8. The printed circuit board as set forth in claim 7, wherein the over-coating layer is made of one-part, thermosetting resin.

9. The printed circuit board as set forth in claim 1, further comprising a solder mask layer for protecting the circuit pattern.

10. The printed circuit board as set forth in claim 1, wherein the metal pad ranges in thickness from 18 to 45 μm.

11. The printed circuit board as set forth in claim 7, wherein the nickel and the gold are plated to a thickness of 3 to 5 μm and 0.05 to 0.08 μm, respectively.

12. The printed circuit board as set forth in claim 1, wherein the resistor is formed of carbon-based resistor paste in which fillers are dispersed.

13. The printed circuit board as set forth in claim 1, wherein the resistor ranges in thickness from 15 to 40 μm.

14. The printed circuit board as set forth in claim 1, wherein the over-coating layer ranges in thickness from 15 to 25 μm.

15. A method for manufacturing a printed circuit board with an embedded resistor, comprising the steps of:
a) building at least one pair of spaced resistor metal pads, along with a circuit pattern, on a resinous insulating substrate;
b) depositing a blanket of a solder mask layer over the resulting substrate structure of the step a);
c) selectively removing the solder mask layer to form a solder mask opening through which the resistor metal pads and the region therebetween is exposed;
d) forming a conductive protective layer onto each of the resistor metal pads to give resistor terminations;
e) forming a thick-film resistor between the resistor terminations with an electrical connection of the resistor to the terminations; and
f) covering the resistor and resistor terminations with an over-coating layer of one-part ink.

16. The method as set forth in claim 15, wherein the conductive protective layer has a bi-layer structure made of nickel and gold.

17. The method as set forth in claim 16, wherein the bi-layer structure is formed by electroless plating nickel and gold.

18. The method as set forth in claim 15, wherein the metal pads are made of copper.

19. The method as set forth in claim 15, wherein the one-part ink is one-part, thermosetting ink.

20. The method as set forth in claim 19, wherein the one-part, thermosetting ink includes 30 to 40% by weight of an epoxy thermosetting resin, 3 to 5% by weight of a thermosetting curing agent, and 50 to 60% by weight of an inorganic filler, as main components thereof.

21. The method as set forth in claim 15, wherein the solder mask layer ranges in thickness from 30 to 40 μm.

22. The method as set forth in claim 15, wherein the metal pads range in thickness from 18 to 45 μm.

23. The method as set forth in claim 17, wherein the nickel and gold are plated to a thickness of 3 to 5 μm and 0.05 to 0.08 μm, respectively.

24. The method as set forth in claim 15, wherein the thick-film resistor is formed by screen-printing carbon-based resistor paste in which fillers are dispersed.

25. The method as set forth in claim 15, wherein the thick-film resistor ranges in thickness from 15 to 40 μm.

26. The method as set forth in claim 15, wherein the over-coating layer ranges in thickness from 15 to 25 μm.

27. The method as set forth in claim 15, further comprising the step of:
trimming the thick-film resistor with a laser to form a groove for controlling the resistance thereof, prior to the step f).

28. The method as set forth in claim 27, wherein the groove comprises a first and a second groove.

29. The method as set forth in claim 28, wherein the first groove is formed in such a way as to penetrate partially through the resistor in d widthwise direction.

30. The method as set forth in claim 29, wherein the first groove is extended to the substrate underneath the resistor.

31. The method as set forth in claim 15, wherein the step f) is carried out by screen-printing the one-part ink, followed by thermally curing at 150 to 170° C.
